(19) United States
(12) Patent Application Publication
(10) Pub. No.: US 2005/0204266 A1
(43) Pub. Date: Sep. 15, 2005

(54) Generalized puncturing in a communication system

(76) Inventors: Ravishankar H. Mahadevappa, Irvine, CA (US); Stephan ten Brink, Irvine, CA (US)

Correspondence Address: CHRISTIE, PARKER & HALE, LLP, PO BOX 7068, PASADENA, CA, 91109-7068, US

(21) Appl. No.: 11/081,327

(22) Filed: Mar. 15, 2005

Related U.S. Application Data
(60) Provisional application No. 60/553,097, filed on Mar. 15, 2004.

(51) Int. Cl. H04B 1/69; H04B 1/707; H04B 1/713; H03M 13/00

(52) U.S. Cl. 714/758

(57) ABSTRACT

A rate adaptation scheme for a wireless transmission system. An information message encoded at a mother rate code is punctured to achieve an adapted rate approximate a selected code rate. The adapted code rate is such that all of the bits transmitted by multi bit symbols, such as OFDM symbols, are used to transmit information of the information message. The use of zero pad bits, or pad bits which cannot provide information regarding entirety of the information message is thereby reduced.

### CROSS-REFERENCE TO RELATED APPLICATION

This application claims the benefit of U.S. Provisional Patent Application No. 60/553,097, filed Mar. 15, 2004 entitled GENERALIZED PUNCTURING IN A COMMUNICATION SYSTEM, the disclosure of which is incorporated herein by reference.

### BACKGROUND

The present invention relates generally to communication systems, and more particularly to coding schemes for use in communication systems using multiple state symbols.

Communication systems are often required to transfer large amounts of information over links of the communication system, and to do so reliably in small amounts of time. Numerous methods may be used for quickly and reliably transmitting information. In some systems information may be transferred at very high rates as binary symbols, with error correction coding used to correct errors generated during transfer. In other systems high transfer rates may also be achieved by mapping multiple binary items of information to a single symbol having multiple possible states. In still other systems high transfer rates may be achieved by transferring information over multiple channels or subchannels of a particular information link.

Considering systems mapping, or modulating, multiple binary items of information to a multiple state symbol, there are numerous mapping schemes which may be used. A common scheme uses Quadrature Amplitude Modulation (QAM), with bit patterns mapped to symbols identifiable by phase shift and amplitude. 16-QAM and 64-QAM schemes, mapping 4 bits and 6 bits, respectively, to a symbol, are common. 128-QAM and 256-QAM schemes are also known, and for these schemes the number of bits per symbol increases to 7 and 8 bits, respectively.

Some wireless communication systems use QAM, and some of those additionally increase link capacity by simultaneously transmitting over multiple effective channels, or subcarriers. In some systems a large number of subcarriers may be used. For example, in 802.11a compliant systems using Orthogonal Frequency Division Multiplexing (OFDM), 48 subcarriers may be available. Effectively, a symbol encodes 288 bits in a system using 64-QAM mapping with 48 subcarriers, and such symbols are sometimes referred to as OFDM symbols.

Depending on a variety of factors, such as the amount of information for transmission, the error correction scheme used, and other factors, some of the bits encoded by a symbol may not be effectively used. In other words, a symbol may encode less information than the symbol is capable of encoding, thereby wasting system bandwidth.

For the 802.11a compliant system discussed above the unused bandwidth may not be considered excessive. As higher order modulation schemes, such as 256-QAM, and multiple subchannels per subcarrier, such as Multiple Input Multiple Output OFDM (MIMO-OFDM) are implemented, however, the number of coded bits per symbol increases tremendously, increasing potential waste of system bandwidth.

### BRIEF SUMMARY OF THE INVENTION

The invention provides in various aspects additional code redundancy for multiple bit symbol transmission systems. Some aspects of the invention provide code redundancy in a wireless transmission system. Some aspects of the invention provide code redundancy in a MIMO-OFDM wireless transmission system. In some aspects code redundancy is provided using rate adaptation. In some aspects rate adaptation is a function of the number of pad bits in a data field. In some aspects rate adaptation is performed by repeating bits or by depuncturing bits.

In one aspect the present invention provides a method for providing increased redundancy in a system transmitting symbols representing multiple bits, comprising encoding an information message of i bits using a code having a first code rate to form an encoded information message of m bits; receiving an indication of a selected code rate; determining a length of the encoded information message of m bits if punctured to the selected code rate; determining a number of symbols required to transmit the encoded information message of m bits if punctured to the selected code rate; and adapting the encoded information message of m bits to an encoded information message of a number of bits represented by the number of symbols.

In another aspect the present invention provides a method for providing increased redundancy in a system transmitting symbols representing multiple bits, comprising encoding an information message of m bits using a code having a first code rate to form an encoded information message of n bits; determining a number of symbols, associated with a selected code rate, required to transmit the n bits; determining a number of bits represented by the number of symbols; adapting the encoded information message of n bits to an encoded information message of the number of bits represented by the number of symbols.

In another aspect the present invention provides a method of determining a code rate of a received message, comprising receiving an indication of an information message length, an indication of a selected code rate, and an indication of a selected modulation scheme; determining a received message length based on the indication of the information message length, the indication of the selected code rate, and the indication of the selected modulation scheme; determining an effective code rate based on a ratio of the indication of the information message length and the received message length; decoding a received message using the effective code rate.

In another aspect the present invention provides a wireless communication system, comprising a mother rate encoding block including circuitry configured to encode an item of information at a mother rate; a data rate determination block including circuitry configured to determine a selected modulation scheme and a selected code rate; a channel encoder block including circuitry configured to adapt the encoded item of information to an adapted code rate based on the selected modulation scheme, the selected code rate, and a length of the encoded item of information if modified to the selected code rate.

In yet another aspect the present invention provides a wireless communication system, comprising a rate calculation block including circuitry configured to determine a selected code rate and a selected modulation scheme based on a selected data rate, and to determine an adapted code rate based on a message length, the selected code rate, a number of transmit antennas, and the selected modulation scheme; a depuncterer block including circuitry configured to depuncture a received message using the adapted code rate; a decoder block including circuitry configured to decode the depunctured received message.

These and other aspects of the invention are more fully comprehended in view of this disclosure, including the associated figures.

### BRIEF DESCRIPTION OF THE DRAWINGS

FIG. 1 is a block diagram of a transmitter for a wireless communication system;

FIG. 2 is a block diagram of a receiver for a wireless communication system;

FIG. 3 is a block diagram of an encoder and puncturer/depuncturer with rate adaptation in accordance with aspects of the invention;

FIG. 4 is a flowchart of a process of determining an adapted rate in accordance with aspects of the invention;

FIG. 5 is a block diagram of a decoder and depuncterer in accordance with aspects of the invention; and

FIG. 6 is a chart of signal to noise ratio versus data rate for a variety of signals.

### DETAILED DESCRIPTION

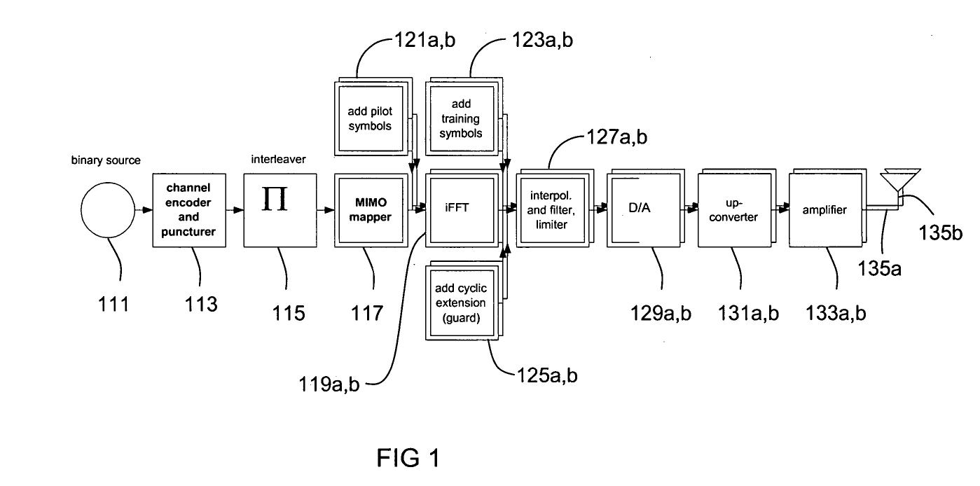

FIG. 1 is a block diagram of a transmitter in a wireless communication system. As illustrated, the transmitter is configured as a two antenna transmitter in a MIMO-OFDM system. The transmitter transmits information provided by a binary source 111. The information from the binary source is channel encoded and rate adapted in discrete length segments by a channel encoder 113. Rate adaptation modifies the code rate of the information to a code rate selected for transmission. In addition, rate adaptation modifies the encoded information to conform to predefined transmission symbol lengths.

As an example, in a transmission system using 864 bit symbols, a message may have 6000 bits of information. The 6000 bits of information are channel encoded using a mother code, for example a ½ rate convolutional code with 2 encoded bits for every information bit. Accordingly, the channel encoded message is 12000 encoded bits. The transmitter selects a ¾ code rate as suitable for transmission. Use of a ¾ code rate for 6000 information bits (12000 encoded bits) would result in a coded message of 8000 bits, with 4000 encoded bits punctured, or removed from the transmission stream. The transmission system transmits using 864 bit symbols, however, and 8000 bits require 10 symbols which provide for transmission of 8640 bits. The channel encoder therefore adapts the code rate to a new effective code rate, with the new effective code rate a function of the selected code rate and the number of extra bits available in view of transmission symbol capacity. In this example, the new effective code rate is 6000/(8000+640), or approximately 0.69444.

The encoded information is interleaved by an interleaver 115, which passes the interleaved information to a MIMO mapper 117. The MIMO mapper maps information to different outputs, or antennas. In some embodiments the MIMO mapper selects code rates, and code rate adaptation is performed by the MIMO mapper instead of by the channel encoder.

The MIMO mapper provides the information to inverse FFT blocks 119a,b, preferably one per output or antenna. Pilot symbols 121a,b are provided with the information, and training 123a,b and guard extensions 125a,b are added to the output of the iFFT blocks. The iFFT outputs are interpolated, filtered and limited 127a,b, passed to digital to analog converters 129a,b, upconverted 131a,b to a transmission carrier frequency, amplified 133a,b, and transmitted via antennas 135a,b.

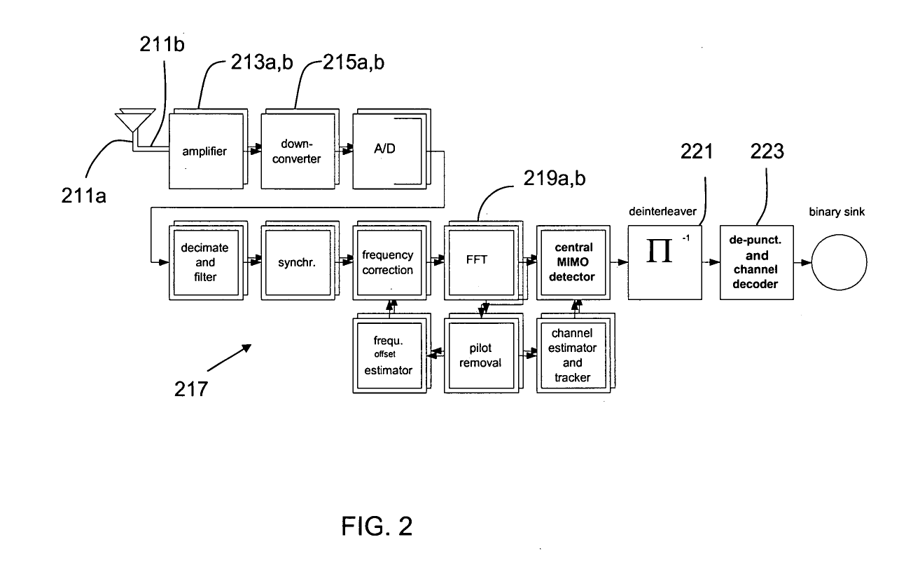

FIG. 2 is a block diagram of a receiver in accordance with aspects of the invention. The receiver receives transmitted information via antennas 211a,b, amplifies the received information using amplifiers 213a,b downconverts the information to a baseband signal using downconverters 215a,b, digitizes the information, and processes the digitized information with various processing blocks 217. The processing blocks include FFT blocks 219a,b and other blocks.

The processed digitized information is deinterleaved by a deinterleaver 221, and passed to a channel decoder 223. The channel decoder depunctures the information and decodes the information using the mother code convolutional code.

In some embodiments the transmitted information includes overhead information, with the overhead information including data rate and message length. In a variety of such embodiments the channel decoder determines the effective code rate based on the data rate, which implicitly provides modulation and coding rate information, and the message length. In some embodiments the overhead information includes an indication of a length of an information message, for example in bits, an indication of a code rate, an indication of a number of bits per modulation symbol, and optimally, a number of transmit antennas.

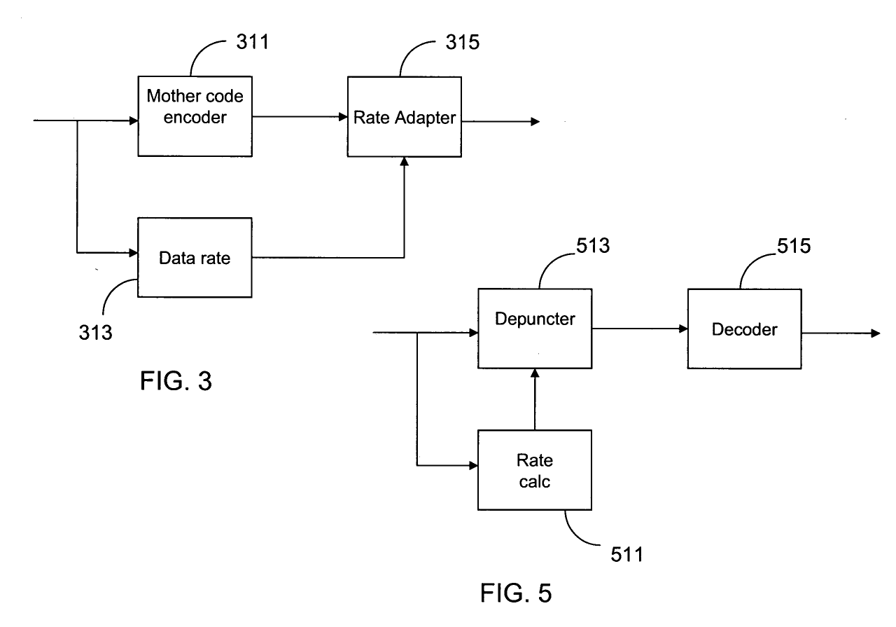

FIG. 3 is a block diagram of a channel encoder in accordance with aspects of the invention. In the channel encoder a mother code encoder 311 receives binary information, the binary information forming a message of a fixed size. The mother code encoder encodes the binary information, preferably with redundant encoding suitable for a particular transmission channel. In some embodiments the mother code is a ½ rate convolutional code.

The encoder also includes a data rate determination block 313. In various embodiments the data rate determination block may not be part of the channel encoder, and the data rate determination block may have its functions performed by various blocks within a transmitter. For increased understanding, however, the data rate determination block is included in the channel encoder of FIG. 2. The data rate determination block selects a data rate for transmission, with the data rate determining both a selected code rate and a modulation scheme. In some embodiments the data rate also determines a number of outputs, for example a number of antennas in a MIMO-OFDM system.

The data rate, and/or selected code rate, modulation scheme, and number of outputs (if pertinent) are provided to a rate adaptation block 315. The rate adaption block also receives the information encoded by the mother code encoder. The rate adaptation block determines an effective code rate for the information based on the message size, the selected code rate, and the modulation scheme. Based on the effective code rate the rate adaptation block punctures the encoded message to achieve the effective code rate. If the effective code rate is less than the mother code rate, however, the rate adaptation block expands portions of the message by repeating message bits. The adaptation block outputs encoded information.

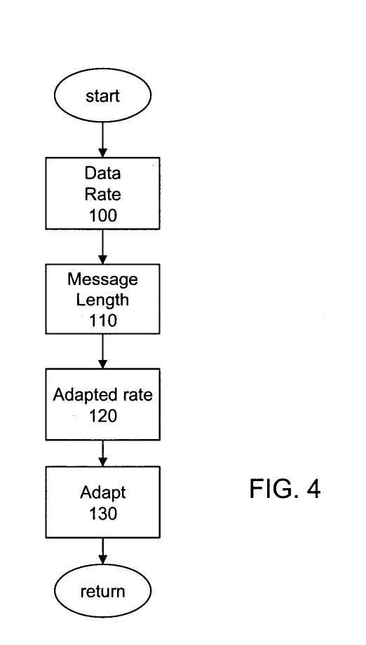

In some embodiments the rate adaptation block performs a process as flow-diagramed in FIG. 4. In block 100 the process determines a data rate. In some embodiments determining a data rate is receiving a signal providing data rate information. In block 110 the process determines a message length. In some embodiments determining a message length is receiving a signal indicative of message length. In block 120 the process determines an adapted code rate. The adapted code rate is a rate approximate a selected code rate, but is modified in view of transmission symbol capacity. In some embodiments the process determines an adapted code rate by determining a ratio between number of information bits and number of transmission bits, for example when the number of transmission bits are in discrete quanta. In block 130 the process adapts a message to the adapted code rate. In some embodiments adapting a message to the adapted code rate includes puncturing bits of a message encoded using a mother code. In some embodiments adapting a message to the adapted code rate includes repeating bits of a message or of a message encoded using a mother code.

In one embodiment a coded message having a length end is received. For example, the coded message has been encoded using convolutional encoded at a code rate Rn. A message is to be transmitted using multi-bit symbols, with each symbol mapping multiple bits. In many instances a final symbol in a transmission message is able to map more bits than the final bits of the message all is provided to map. In other words, the symbols used to transmit a message with capabilities to transmit the message and an additional number of bits. Accordingly, the coded message of length n is punctured according to a puncturing pattern, or includes repeating bits according to a repeating pattern, to adapt a message to a new code rate.

In one embodiment a repetition/puncturing pattern is determined as follows. A sequence of indices from 1 to n is each multiplied by a ratio of the number of bits mapped by the information symbols and the number of bits of the coded message. This sequence is then rounded to the nearest integer greater than or equal to each member of the sequence to form a new sequence. A further sequence which is the new sequence with a preceding zero indice is then formed. A repetition/puncturing pattern is then formed by calculating differences between adjacent elements of the further sequence. In other words, if n_new is the total number of bits mapped by the symbols for transmitting the message, and n is the coded message length, then
new_seq=ceil ((1:n)* n_new/n); and rep/pct_pattern=diff([0 new_seq]).

FIG. 5 is a block diagram of a decoder in accordance with aspects of the invention. The decoder receives demodulated information. The demodulated information has been encoded using a mother code, and then adapted to an adapted code rate. The decoder includes a rate adaptation calculation block 511. The rate adaptation calculation block determines the adapted code rate. In some embodiments the rate adaptation calculation block determines the adapted code rate using information received with overhead associated with the demodulated information.

The demodulated information is received by a depuncterer/decoder 513. The depuncterer/decoder modifies the received information by resolving the rate adaptation. The received information is resolved by depuncturing the received information, if the received information has an adapted code rate greater than the mother code rate. In embodiments where the adapted code rate is less than the mother code rate the depuncterer/decoder removes repetitions or other additional information in the received information, using the repetitions or other information to correct the received information. The resolved information, which is now at the mother code rate, is provided to a decoder 515. The decoder decodes the resolved information, in some embodiments by decoding the mother code.

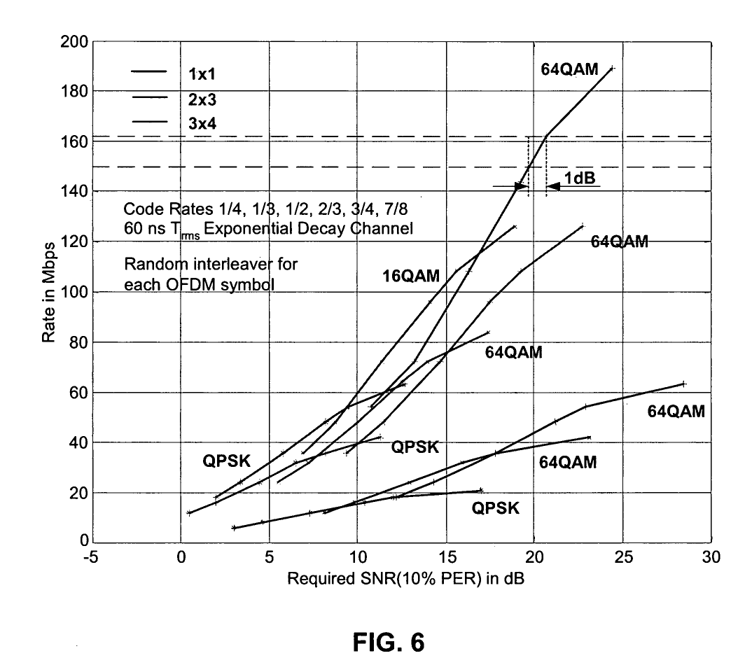

FIG. 6 is a chart of simulated signal to noise ratio in dB versus data rate in Mbps for various signals. The chart indicates that using rate adaptation may result in a 1 dB improvement in signal to noise ratio for some signals.

The invention therefore provides rate adaptation in a communication system. Although the invention has been described with respect to particular embodiments, it will be recognized that the invention includes the claims and their equivalents supported by this disclosure.

1. A method for providing increased redundancy in a system transmitting symbols representing multiple bits, comprising:
encoding an information message of i bits using a code having a first code rate to form an encoded information message of m bits;
receiving an indication of a selected code rate;
determining a length of the encoded information message of m bits if punctured to the selected code rate;
determining a number of symbols required to transmit the encoded information message of m bits if punctured to the selected code rate;
adapting the encoded information message of m bits to an encoded information message of a number of bits represented by the number of symbols.

2. The method of claim 1 wherein adapting the encoded information message of m bits to an encoded information message of the number of bits represented by the number of symbols comprises puncturing at least some of the m bits.

3. The method of claim 1 wherein adapting the encoded information message of m bits to an encoded information message of the number of bits represented by the number of symbols comprises repeating at least some of the m bits.

4. The method of claim 1 wherein adapting the encoded information message of n bits to an encoded information message of the number of bits represented by the number of symbols comprises puncturing at least some of the m bits to form a selected code rate encoded information message and unpuncturing at least some of the punctured bits to form an encoded information message of the number of bits represented by the number of symbols.

5. The method of claim 1 further comprising transmitting symbols representing the encoded information message of the number of bits represented by the number of symbols.

6. The method of claim 5 further comprising transmitting an indication of the number of bits of the encoded information message of n bits and an indication of the number of bits represented by the number of symbols.

7. The method of claim 6 wherein the indication of the number of bits represented by the number of symbols is a selected data rate.

8. The method of claim 7 wherein the selected data rate indicates a selected code rate and a modulation scheme.

9. The method of claim 5 wherein transmitting the symbols representing the encoded information message of the number of bits represented by the number of symbols comprises transmitting over a plurality of antennas.

10. The method of claim 9 further comprising transmitting an indication of the number of bits of the encoded information message of n bits, an indication of the number of bits represented by the number of symbols, and an indication of the number of the plurality of antennas.

11. The method of claim 10 wherein the indication of the number of bits represented by the number of symbols is a selected data rate.

12. The method of claim 11 wherein the selected data rate indicates a selected code rate and a modulation scheme.

13. A method for providing increased redundancy in a system transmitting symbols representing multiple bits, comprising:
encoding an information message of m bits using a code having a first code rate to form an encoded information message of n bits;
determining a number of symbols, associated with a selected code rate, required to transmit the n bits;
determining a number of bits represented by the number of symbols;
adapting the encoded information message of n bits to an encoded information message of the number of bits represented by the number of symbols.

14. The method of claim 13 wherein adapting the encoded information message of n bits to an encoded information message of the number of bits represented by the number of symbols comprises puncturing at least some of the n bits.

15. The method of claim 13 wherein adapting the encoded information message of n bits to an encoded information message of the number of bits represented by the number of symbols comprises repeating at least some of the n bits.

16. The method of claim 13 wherein adapting the encoded information message of n bits to an encoded information message of the number of bits represented by the number of symbols comprises puncturing at least some of the n bits to form a selected code rate encoded information message and unpuncturing at least some of the punctured bits to form an encoded information message of the number of bits represented by the number of symbols.

17. The method of claim 13 further comprising transmitting symbols representing the encoded information message of the number of bits represented by the number of symbols.

18. The method of claim 17 further comprising transmitting an indication of the number of bits of the encoded information message of n bits and an indication of the number of bits represented by the number of symbols.

19. The method of claim 18 wherein the indication of the number of bits represented by the number of symbols is a selected data rate.

20. The method of claim 19 wherein the selected data rate indicates a selected code rate and a modulation scheme.

21. The method of claim 17 wherein transmitting the symbols representing the encoded information message of the number of bits represented by the number of symbols comprises transmitting over a plurality of antennas.

22. The method of claim 21 further comprising transmitting an indication of the number of bits of the encoded information message of n bits, an indication of the number of bits represented by the number of symbols, and an indication of the number of the plurality of antennas.

23. The method of claim 22 wherein the indication of the number of bits represented by the number of symbols is a selected data rate.

24. The method of claim 23 wherein the selected data rate indicates a selected code rate and a modulation scheme.

25. A method of determining a code rate of a received message, comprising:
receiving an indication of an information message length, an indication of a selected code rate, and an indication of a selected modulation scheme;
determining a received message length based on the indication of the information message length, the indication of the selected code rate, and the indication of the selected modulation scheme;
determining an effective code rate based on a ratio of the indication of the information message length and the received message length;
decoding a received message using the effective code rate.

26. The method of claim 25 wherein the indication of the selected code rate and the indication of a selected modulation scheme are provided by an indication of a selected data rate.

27. The method of claim 25 further comprising receiving an indication of a number of transmit antennas.

28. The method of claim 27 wherein determining a received message length is further based on the indication of the number of transmit antennas.

29. The method of claim 28 wherein the selected modulation scheme comprises a QAM scheme.

30. A wireless communication system, comprising:
a mother rate encoding block including circuitry configured to encode an item of information at a mother rate;
a data rate determination block including circuitry configured to determine a selected modulation scheme and a selected code rate;
a channel encoder block including circuitry configured to adapt the encoded item of information to an adapted code rate based on the selected modulation scheme, the selected code rate, and a length of the encoded item of information if modified to the selected code rate.

31. A wireless communication system, comprising:
a rate calculation block including circuitry configured to determine a selected code rate and a selected modulation scheme based on a selected data rate, and to determine an adapted code rate based on a message length, the selected code rate, a number of transmit antennas, and the selected modulation scheme;
a depuncterer block including circuitry configured to depuncture a received message using the adapted code rate;
a decoder block including circuitry configured to decode the depunctured received message.

32. A method of adapting a code rate in a communication scheme communicating encoded information of length n=1,2,3, . . . using message units lengths selected from a subset of n=2,3, . . . , comprising:
determining a length of a communication message;
determining a message unit length;
determining a number of message units required to communicate the communication message; and
determining a code rate such that each message unit includes only information of the communications message.

33. The method of claim 32 wherein the communication message includes a tail message.

34. A method of increasing code redundancy in a multiple bit transmission system, comprising:
receiving an information message for transmission;
determining a length of the information message;
determining a length of a communication message comprised of a number of symbols, each symbol encoding information of multiple bits; and
determining a code rate such that each symbol of the communication message includes only encoded information of the information message.

35. A method of adapting a code rate, comprising:
encoding an information message using a mother rate code;
determining a data rate, the data rate determining a selected code rate and a modulation scheme;
determining an effective code rate based on the length of the mother rate encoded information message and the data rate;
adapting the mother rate encoded information message to the effective code rate.

36. The method of claim 35 wherein determining the effective code rate comprises determining a ratio between a length of the encoded information message and a length of a transmission message for the information message.

37. A method of adapting a communication rate, comprising:
encoding an information message using a mother code having a mother code rate to form a mother rate encoded information message;
receiving a selected code rate of a discrete set of code rates;
puncturing the mother rate encoded information message to form a selected code rate encoded information message;
determining a length of a transmission message for the selected code rate encoded information message;
determining an adapted code rate based on a ratio of a length of the information message and the length of the transmission message; and
adapting the selected code rate encoded information message to an adapted code rate encoded information message.
